(19) United States
(12) Patent Application Publication
(10) Pub. No.: US 2008/0054492 A1
(43) Pub. Date: Mar. 6, 2008

(54) Semiconductor device and method for manufacturing the same

(75) Inventor: Dong Ki Jeon, Gangneung-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 11/893,866

(22) Filed: Aug. 17, 2007

(30) Foreign Application Priority Data
Aug. 29, 2006 (KR) 10-2006-0082499

(51) Int. Cl. H01L 23/48; H01L 21/44

(52) U.S. Cl. 257/784; 438/656; 257/E23.01; 257/E21.476

(57) ABSTRACT

A semiconductor device may include a metal wiring formed on a substrate; a Ti film formed on the metal wiring; a TiN film formed on the Ti film; and an ultra-fine Ti film formed on the TiN.

The present application claims the benefit under 35 U.S.C. § 119 of Korean Patent Application No. 10-2006-0082449, filed Aug. 29, 2006, which is hereby incorporated by reference in its entirety.

### BACKGROUND

Generally, titanium nitride (TiN) is frequently used as barrier metal for preventing the diffusion between an intermetal dielectric (IMD) and a metal wiring of a semiconductor device. However, compressive stress of a TiN film is relatively large, so that if an annealing process is performed after the formation of the IMD, the phenomenon (Circle Defect) (D) that the IMD film comes off due to the stress between the TiN film and the IMD film may be caused.

FIG. 1 is across-sectional photograph of the circle defect generated in a semiconductor device according to the related art, wherein a TiN film 40 thermally expands to compress an intermetal dielectric (IMD). However, it can be appreciated that the thermal expansion of the intermetal dielectric is low relative to TiN, which may cause the circle defect (D) phenomenon and result in the intermetal dielectric ultimately breaking and coming off.

### BRIEF SUMMARY

Embodiments of the invention are intended to provide a semiconductor device and a method for manufacturing the same, capable of preventing or reducing the incidence of the circle defect by fabricating a TiN film having a relatively small stress.

The semiconductor device according to one embodiment comprises a metal wiring on a substrate; a Ti film on the metal wiring; a TiN film on the Ti film; and an ultra-fine Ti film on the TiN.

In addition, the method for manufacturing the semiconductor device according to another embodiment comprises the steps of: forming a Ti film on a metal wiring on a substrate; forming a TiN film on the Ti film; and forming an ultra-fine Ti film on the TiN film.

### BRIEF DESCRIPTION OF THE DRAWINGS

FIG. 1 is across-sectional view of circle defect generated in a semiconductor device according to the related art.

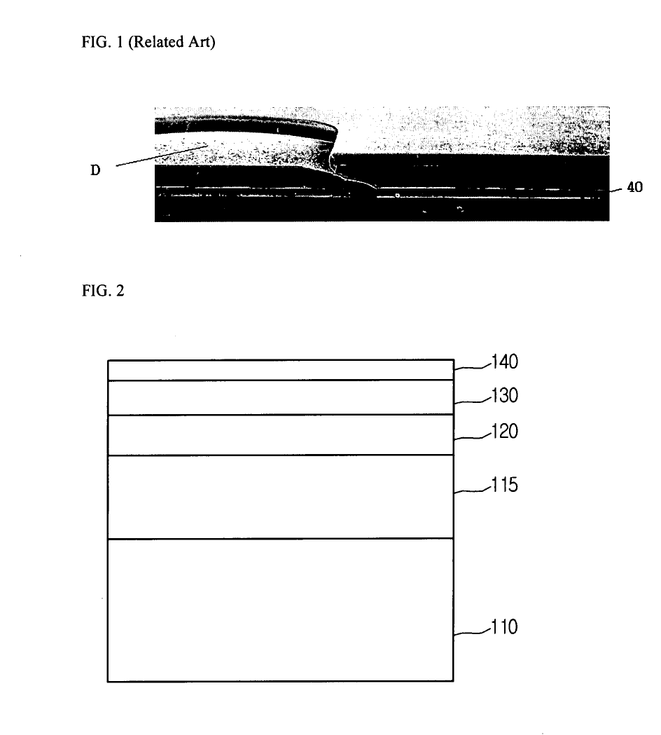

FIG. 2 is a cross-sectional view of a semiconductor device according to the embodiment.

FIGS. 3 to 5 are cross-sectional views of a process for manufacturing the semiconductor device according to the embodiment.

### DETAILED DESCRIPTION OF TH EMBODIMENTS

Hereinafter, a semiconductor device and a method for manufacturing the same will be described with reference to accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, and one or more intervening layers may also be present. In addition, it will also be understood that when a layer is referred to as being ‘between’ two layers, it can be the only layer between the two layers, or one or more intervening layers may also be present.

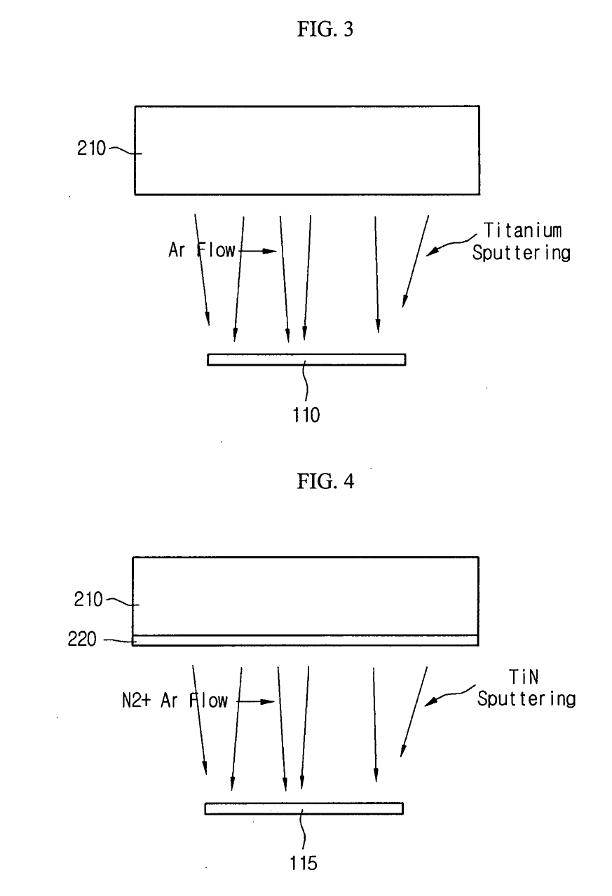

FIG. 2 is a cross-sectional view of a semiconductor device according to one embodiment. The semiconductor device according to FIG. 2 comprises: a metal wiring 115 on a substrate 110; a Ti film 120 on the metal wiring; a TiN film 130 on the Ti film; and an ultra-fine Ti film 140 on the TiN film.

The metal wiring 115 can comprise an Al wiring, a Cu wiring, a W (tungsten) wiring, a combination thereof, or an alloy thereof (e.g., Al—Cu alloy).

The ultra-fine Ti film 40 generally refers to a TiN film having a very thin thickness, and is referred to as a flash Ti film herein. For example, the ultra-fine film 140 may have a thickness of 5 to 30 Å, which is generally effective to prevent or reduce the incidence of the circle defect and/or reduce the stress between the TiN and an intermetal dielectric. In the case where the ultra-fine Ti film 140 is less than 5 Å, it may be difficult to satisfactorily lower the stress. Also, in the case where the ultra-fine film 140 exceeds 30 Å, since the Ti film normally has a silver color above such a thickness, the Ti film may reflect light in a subsequent photolithographic process and adversely affect the function of an anti-reflective coating (ARC) that the TiN film may provide.

That is, with the semiconductor device according to the embodiments of the invention, it has an effect that the Ti film having a low stress contacts to the IMD film to suppress the generation of the circle defect, thereby making it possible to improve yield. In addition, with some embodiments, it has an effect that a very thin Ti film (5˜30 Å) is used so that the original characteristics of the TiN and/or ARC layer can be maintained. Also, with other embodiments, it has an effect that a Ti film having relatively good adhesion characteristics with the IMD is formed by a Ti flash method, which can improve the reliability of the device.

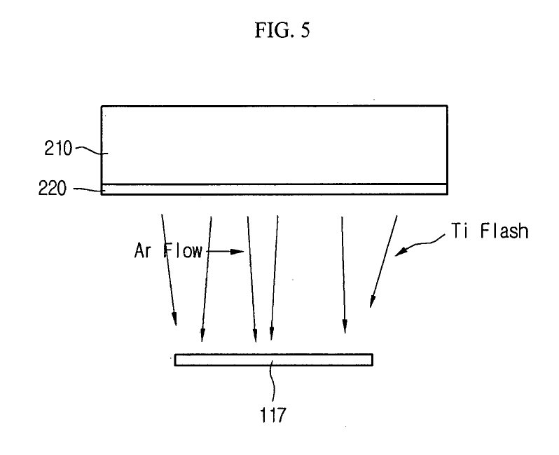

FIGS. 3 to 5 are cross-sectional views of a process for manufacturing the semiconductor device according to the embodiment. Hereinafter, the process for manufacturing the semiconductor device according to the embodiment will be described with reference to the FIGS. 3 to 5 and Table 1 below.

TABLE 1
TiN + Ti Flash Deposition Recipe Description

| | Step # | | | | | |
|---|---|---|---|---|---|---|
| | 1 | 2 | 3 | 4 | 5 | 6 |
| Name | Gas | Ignition | TiN dep | Gas | Ti flush | Pump |
| time | 7 | 3 | ** | 7 | ** | 5 |
| position | process | process | process | process | process | process |
| DC | | 500 | 6500 | | 1000 | |
| power(w) | | | | | | |
| Ramp | | 500 | 6500 | | 1000 | |
| up(w) | | | | | | |
| N₂ | 70 | 40 | 55 | | | |
| flow(scc) | | | | | | |
| AR | 70 | 55 | 55 | 55 | 55 | |
| flow(scc) | | | | | | |

In the process for manufacturing the semiconductor device according to one embodiment, as in Step 1 of the table 1, N₂ and Ar are first flowed into a chamber (not shown) at a rate of about 70 sccm for about seven seconds. Thereafter (not shown in Table 1), a voltage is applied to the chamber to ignite the plasma. At this time, Ar at a rate of about 55 sccm is flowed into the chamber for about three seconds. At this time, N₂ gas is not flowed in order to prevent TiN from being formed.

Subsequently, as shown in the FIG. 3, a Ti film 120 is formed on the metal wiring 115 on the substrate 110 using Ti target material 210 (e.g., by sputtering). At this time, the deposition process is performed for a predetermined time while flowing Ar at a rate of about 55 sccm into the chamber. At this time, the process time can be controlled depending on the thickness for the Ti film 120. The deposition speed of the Ti film relies on DC power, (electrode) voltage and chamber and/or substrate temperature, etc. According to the present recipe, the Ti film is deposited at a speed of about 10˜15 Å/sec.

If the N₂ gas is supplied, TiN is formed. Thus, the supply of the N₂ gas should also be blocked during deposition of Ti.

Next (not shown in Table 1), N₂ and Ar gasses are flowed at rates of about 70 sccm each for about seven seconds into the chamber (not shown). Thereafter, as shown in Step 2, a voltage and/or Dc power is applied to the chamber to ignite another plasma. At this time, N₂ is flowed at a rate of about 44 sccm and Ar is flowed at a rate of about 55 sccm into the chamber for about three seconds.

In Step 3, and as shown in FIG. 4, a TiN film 130 is formed (e.g., by sputtering) using the Ti target material (210) on the substrate 115 having the Ti film formed on the metal wiring. At this time, the Ar and the N₂ gases are flowed at a rate of about 55 sccm for a predetermined time into the chamber (not shown), respectively. The process time can also be controlled depending on the thickness for forming the TiN film 130. The deposition speed of the TiN film relies on the DC power, the voltage, the chamber and/or substrate temperature, etc. Here, the TiN film is deposited at a speed of about 10 to 15 Å/sec. At this time (e.g., during Step 3), on the surface of the Ti target material 210, a thin TiN layer 220 can be formed by reaction with and/or exposure to the N₂ gas.

Next, as shown in Step 4, Ar at a rate of about 55 sccm is flowed into the chamber for about seven seconds.

Thereafter, as shown in Step 5, a DC power and/or voltage is applied to the chamber to ignite another plasma. At this time, a flash deposition process is performed in the Ar atmosphere (flowed at a rate of about 55 sccm for about 0.5 to 3 seconds) to form the ultra-fine Ti film.

The ultra-fine Ti film 140 can have a thickness of about 5 to 30 Å in the Ar atmosphere (e.g., by sputtering) using the Ti target material 210. For example, a Ti film 140 having a thickness of about 5 to 30 Å is generally able to effectively prevent the circle defect without imparting excess or defect-inducing stress on the intermetal dielectric. In the case where the Ti film 140 has a thickness less than 5 Å, it may be difficult to lower the stress. Also, in the case where the Ti film 140 exceeds 30 Å, the Ti film may reflect light and adversely affect the function of an anti-reflective coating (ARC), such as the TiN film.

Also, in some embodiments, the Ti target material 210 having TiN formed on the surface can be used for forming the ultra-fine Ti film 140.

Also, in various embodiments, the Ti target material 210 for forming the ultra-fine Ti film 140 may comprise or consist essentially of a pure Ti target material (e.g., pure Ti).

In particular, the process for forming the ultra-fine Ti film 140 in the embodiment has beneficial effects in that it can be performed in-situ in the same chamber for forming the TiN film 130, so that it can be made by modifying the recipe and without requiring an additional chamber, so that throughput is improved.

Subsequently, as shown in Step 6, the process is finished by pumping the chamber and unloading the substrate on which the ultra-fine Ti film 140 is formed.

As described above, with the semiconductor device and the method for manufacturing the same according to embodiments of the invention, it has effects as follows.

First, with one embodiment, it has an effect that a Ti/Tin thin film on the upper surface of metal wiring (e.g., AlCu alloy) can have a very thin film (5 to 30 Å) of Ti deposited thereon in the same chamber as the TiN was deposited, so that it can be made by modifying the recipe without requiring an additional chamber, and throughput is improved.

Second, a Ti film having a relatively low stress contacts the IMD film to suppress the generation of the circle defect, thereby making it possible to improve yield.

Third, a very thin Ti film (5˜30 Å) is used to maintain the original characteristics of the (TiN) ARC layer.

Fourth, a Ti film having relatively good adhesion characteristics with the IMD can be formed by a Ti flash deposition method so that the reliability of the device is improved.

Fifth, a periodic dummy process (e.g., by which a Ti sputtering process is monitored using a dummy wafer) to monitor the characteristics of the TiN chamber and deposition process may be avoided, thereby improving the throughput of the equipment and reducing the manufacturing cost.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a metal wiring on a substrate;
a Ti film on the metal wiring;
a TiN film on the Ti film; and
an ultra-fine Ti film on the TiN.

2. The semiconductor device according to claim 1, wherein
the ultra-fine Ti film has a thickness of 5 to 30 Å.

3. A method for manufacturing a semiconductor device comprising the steps of:
forming a Ti film on a metal wiring on a substrate;
forming a TiN film on the Ti film; and
forming an ultra-fine Ti film on the TiN film.

4. The method according to claim 3, wherein the step of forming the ultra-fine Ti film comprises sputtering Ti in an atmosphere of Ar gas using a Ti target material.

5. The method according to claim 4, wherein in the ultra-fine Ti film has a thickness of about 5 to 30 Å.

6. The method according to claim 3, wherein the ultra-fine Ti has a thickness of about 5 to 30 Å.

7. The method according to claim 3, wherein the step of forming the ultra-fine Ti film comprises sputtering Ti in an atmosphere of the Ar gas for about 0.5 to 3 seconds using a Ti target material.

8. The method according to claim 7, wherein the step of forming the ultra-fine Ti film comprises depositing TiN from the surface of a Ti target material.

9. The method according to claim 7, wherein the Ti target material consists essentially of pure Ti.

10. The method according to claim 7, wherein the steps of forming the TiN film and the ultra-fine Ti film are performed in-situ in a same chamber.

11. The method according to claim 7, wherein the metal wiring comprises an Al wiring.

12. The method according to claim 7, wherein the metal wiring comprises Al and Cu wirings. [FIX?]
